(19) United States
(12) Patent Application Publication
(10) Pub. No.: US 2015/0144976 A1
(43) Pub. Date: May 28, 2015

(54) LED WITH LIGHT DIVERGENT LENS

(71) Applicant: Hon Hai Precision Industry Co., Ltd., New Taipei (TW)

(72) Inventors: CHAU-JIN HU, Tu-Cheng (TW); FENG-YUEN DAI, Tu-Cheng (TW); PO-CHOU CHEN, Tu-Cheng (TW)

(73) Assignee: HON HAI PRECISION INDUSTRY CO., LTD., New Taipei (TW)

(21) Appl. No.: 14/101,364

(22) Filed: Dec. 10, 2013

(30) Foreign Application Priority Data
Nov. 27, 2013 (TW) 102143337

(51) Int. Cl. H01L 33/58; H01L 33/60; H01L 33/48

(52) U.S. Cl. CPC H01L 33/58; H01L 33/483; H01L 33/60
USPC 257/98

(57) ABSTRACT

An LED includes a base, a chip mounted on the base and a lens covering the chip. The lens has a light incident face contacting the chip and a light emerging face away from the chip. The light emerging face includes a first face confronting the chip and a second face surrounding the first face. The first face is a conical face having a diameter gradually decreasing towards the chip, and the second face is a conical face having a diameter gradually increasing towards the chip.

### BACKGROUND

1. Technical Field

The disclosure generally relates to LEDs (light emitting diodes), and more particularly, to an LED having a light divergent lens.

2. Description of Related Art

Nowadays LEDs (light emitting diodes) are applied widely in various applications for illumination. The LED is a highly pointed light source. In order to illuminate a large area, a concave lens is used with the LED to diverge the light emitted from the LED. However, the light diverging capability of the typical concave lens is still insufficient, resulting in an undesirable light distribution.

What is needed, therefore, is an LED with a light divergent lens which can address the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the various views.

FIG. 1 is an isometric view of an LED in accordance with an embodiment of the present disclosure.

FIG. 2 is a cross section of the LED of FIG. 1, taken along line II-II thereof.

FIG. 3 shows a light distribution of the LED of FIG. 1.

### DETAILED DESCRIPTION

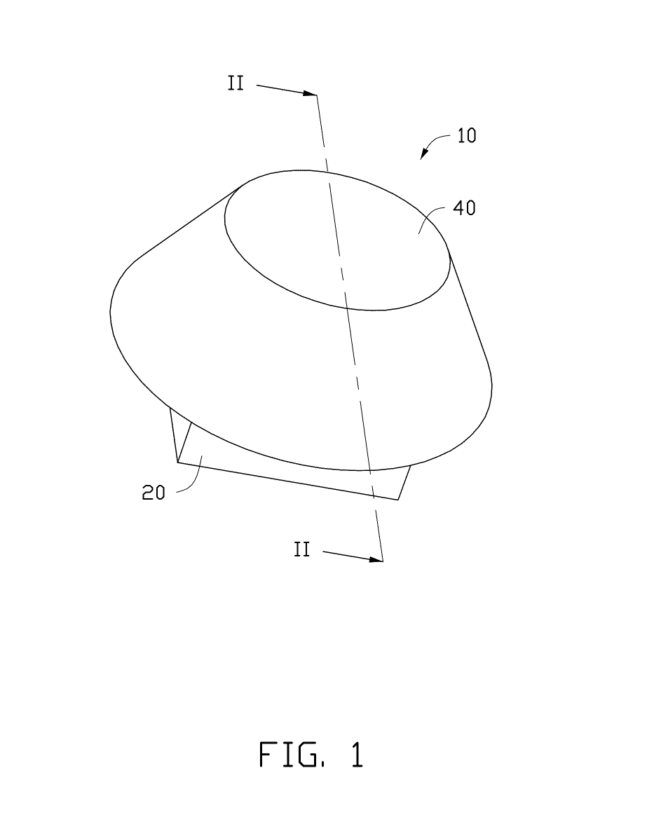

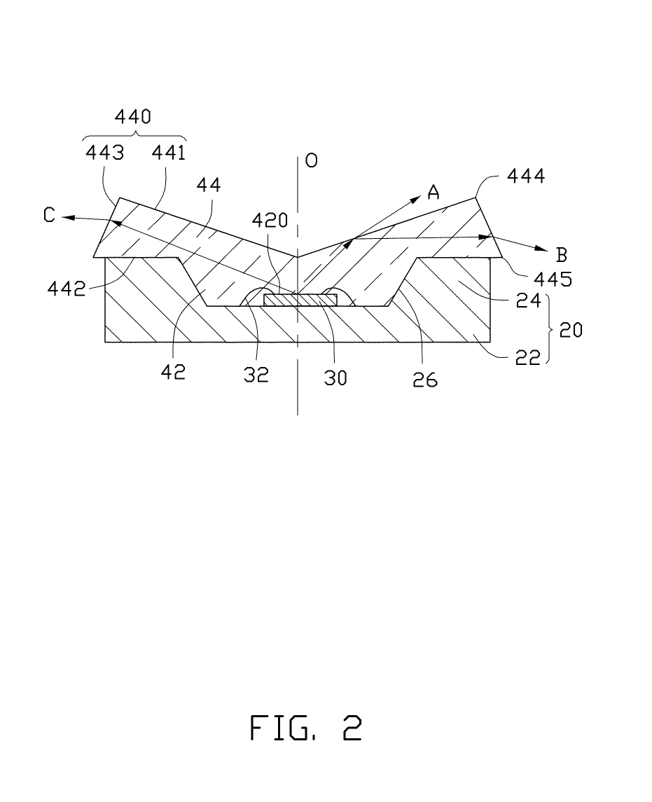

Referring to FIGS. 1-2, an LED (light emitting diode) 10 in accordance with an embodiment of the present disclosure is shown. The LED 10 includes a base 20, a chip 30 mounted on the base 20 and a lens 40 sealing the chip 30. The LED 10 has a central axis O extending through centers of the base 20, the chip 30 and the lens 40.

The base 20 may be integrally made of a single monolithic piece of insulative material such as epoxy, silicone, ceramic or the like. The base 20 includes a plate 22 and a reflective cup 24 formed on a top face of the plate 22. The plate 22 is rectangular and thinner than the reflective cup 24. An inner circumferential face of the reflective cup 24 surrounds a cavity above the plate 22. The cavity has a diameter gradually increasing in a direction away from the plate 22. The inner circumferential face of the reflective cup 24 acts as a light reflective face 26 of the base 20 for reflecting light emitted from the chip 30 upwardly.

The chip 30 is fixed on the top face of the plate 22. The chip 30 may be made of semiconductor material such as GaN, InGaN, AlInGaN or the like. The chip 30 is electrically connected to leads (not visible) formed on the base 20 via two wires 32. The chip 30 can emit light when being activated.

The lens 40 includes a lower part 42 filling the cavity of the base 20 and an upper part 44 located above and outside the cavity of the base 20. The lower part 42 and the upper part 44 of the lens 40 are integrally made of a single monolithic piece of transparent material such as epoxy, silicone or glass. The lower part 42 is tapered and has a diameter gradually increasing in a direction away from the chip 30. The lower part 42 covers the chip 30 to seal the chip 30 from an outside environment. An inner face of the lower part 42 contacting the chip 30 acts as a light incident face 420 of the lens 40. The light emitted from the chip 30 enters the lens 40 through the light incident face 420.

The upper part 44 includes a light emerging face 440 and a connecting face 442 joined to the light emerging face 440. The light emerging face 440 includes a first face 441 and a second face 443 surrounding the first face 441. The first face 441 is a conical face having a diameter gradually decreasing in a direction towards the chip 30. The first face 441 has a lowest point located on the central axis O. Preferably, an inner angle defined between the first face 441 and the central axis O ranges between 130 degrees and 165 degrees. The second face 443 is a conical face having a diameter gradually increasing in a direction towards the chip 30. An inner angle defined between the second face 443 and the central axis O ranges between 0 and 35 degrees. The second face 443 has an area less than that of the first face 441 and larger than that of the light reflective face 26. A junction between the first face 441 and the second face 443 forms a first circle 444 which is located a highest position of the light emerging face 440. The first circle 444 is located within an outer circumferential periphery of the base 20. In other words, a diameter of the first circle 444 is less than an outer diameter of the base 20.

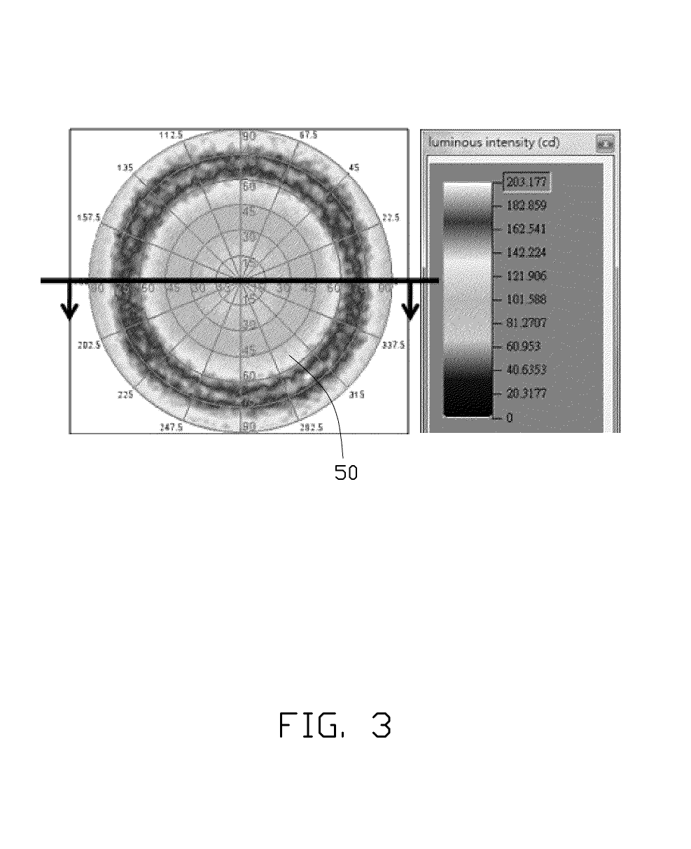

Also referring to FIG. 3, a part of the light emitted from the chip 30 (such as light A shown in FIG. 2) is directly refracted by the first face 441 of the light emerging face 440 to diverge out of the lens 40. Another part of the light emitted from the chip 30 (such as light B shown in FIG. 2) is reflected by the first face 441 towards the second face 443, and then refracted by the second face 443 to diverge out of the lens 40. Remaining part of the light emitted from the chip 30 (such as light C shown in FIG. 2) is directly refracted by the second face 443 to diverge out of the lens 40. Thus, all the light emitted from the chip 30 can be effectively diverged by the lens 40 to thereby form a light distribution 50 illuminating a large area.

The connecting face 442 is located below the light emerging face 440. The connecting face 442 connects a top of the reflective face 26 with a bottom of the second face 443. The connecting face 442 is an annular face parallel to the top face of the plate 22. The connecting face 442 extends outwardly beyond the outer circumferential periphery of the base 20. A junction between the connecting face 442 and the second face 443 forms a second circle 445 located outside the outer circumferential periphery of the base 20. The diameter of the first circle 444 is larger than an inner diameter of the connecting face 442 and smaller than triple the inner diameter of the connecting face 442. The connecting face 442 has an area larger than that of the second face 443 and less than the first face 441.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. An LED (light emitting diode) comprising:
a base having a plate and a reflective cup formed on a top end of the plate;
a chip mounted on the plate of the base and surrounded by the reflective cup; and
a lens covering the chip, the lens comprising a lower part filling in the reflective cup and an upper portion formed on above of the reflective cup, the bottom portion comprising a light incident face and the upper portion comprising a light emerging face, the light emerging face comprising a first face confronting the chip and a second face surrounding the first face, the upper portion further comprising a connecting face contacting a top surface of the reflective cup and connecting a bottom end of the second face, the first face being a smooth conical face and having a V-shaped cross section, the second face extending downwardly from a top end of the first face to an outer periphery of the connecting face, the first face having a diameter gradually decreasing in a direction towards the chip, and the second face having a diameter gradually increasing in a direction towards the chip, the bottom end of the second face and the outer periphery of the connecting face located beyond an outer circumferential periphery of the reflective cup, and a top end of the second face located at inside of the outer circumferential periphery of the reflective cup.

2. (canceled)

3. The LED of claim 1, wherein the second face is a conical face.

4. The LED of claim 1, wherein the first face has an area larger than that of the second face.

5. (canceled)

6. The LED of claim 1, wherein the lower part and the upper part of the lens are made of a single monolithic piece of transparent material.

7.-8. (canceled)

9. The LED of claim 1, wherein the reflective cup forms a reflective face having a diameter gradually increasing in a direction towards the light emerging face.

10. The LED of claim 9, wherein the reflective face has an area less than that of the second face.

11.-12. (canceled)

13. The LED of claim 1, wherein a junction of the first face and the second face is located within the outer circumferential periphery of the base.

14. The LED of claim 1, wherein the connecting face is an annular face.

15. The LED of claim 1, wherein the connecting face has an inner diameter less than an outer diameter of the first face.

16. The LED of claim 1, wherein the outer diameter of the first face is less than triple the inner diameter of the connecting face.

17. The LED of claim 1, wherein the connecting face has an area larger than that of the second face and less than that of the first face.

18. The LED of claim 1, wherein the lens has a central axis, the lowest point of the first face is located on the central axis and is located at a central of the chip.

19. The LED of claim 18, wherein an inner angle defined between the second face and the central axis ranges between 0 and 35 degrees.

20. The LED of claim 19, wherein an inner angle defined between the first face and the central axis ranges between 130 degrees and 165 degrees.
